(19) United States
(12) Patent Application Publication
(10) Pub. No.: US 2026/0361323 A1
(43) Pub. Date: Nov. 12, 2026

(54) Data Storage Device and Method for Reducing Decoder Power Via Incremental Syndrome Calculation and/or Direct Error Locator Polynomial Root Derivation

(71) Applicant: Sandisk Technologies, Inc., Milpitas, CA (US)

(72) Inventors: Eran Sharon, Rishon Lezion (IL); Ran Zamir, Ramat Gan (IL); Idan Goldenberg, Ramat Hasharon (IL); Ishai Ilani, Dolev (IL)

(73) Assignee: Sandisk Technologies, Inc., Milpitas, CA (US)

(21) Appl. No.: 19/199,692

(22) Filed: May 6, 2025

(51) Int. Cl. H03M 13/15; H03M 13/00

(52) U.S. Cl. CPC H03M 13/159; H03M 13/611

(57) ABSTRACT

Error correction codes can be used to identify and correct errors after reading a codeword of data from a memory of a data storage device. After reading the codeword, the data storage device can calculate the syndrome, calculate an error locator polynomial from the syndrome, find the error locations and error values from the error locator polynomial, and correct the errors. Some embodiments presented herein use an incremental syndrome calculation that can provide high throughput, low latency, and low power consumption. Other embodiments presented herein use a look-up table to find the error locations and error values from the error locator polynomial.

### BACKGROUND

Error correction codes can be used to identify and correct errors after reading a codeword of data from a memory of a data storage device. In operation, after reading the codeword of data from the memory, the data storage device can calculate the syndrome, calculate an error locator polynomial from the syndrome, find the error locations and error values as the zeros of the error locator polynomial, and correct the errors.

### BRIEF DESCRIPTION OF THE DRAWINGS

FIG. 1A is a block diagram of a data storage device of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the data storage device illustrated in FIG. 1A according to an embodiment.

FIG. 2B is a block diagram illustrating components of the data storage device illustrated in FIG. 1A according to an embodiment.

FIG. 3 is a block diagram of a host and a data storage device of an embodiment.

FIG. 4 is a diagram showing a High Bandwidth Memory (HBM) architecture and a High Bandwidth Flash (HBF) plus HMB architecture of an embodiment.

FIG. 5 is a graph showing a distribution of errors.

FIG. 6 is an illustration of a decoding pipeline of a Bose-Chaudhuri-Hocquenghem (BCH) decoder of an embodiment.

FIG. 7 is an illustration of a decoding pipeline of an embodiment.

FIG. 8 is a flow chart of a method of an embodiment for reducing decoder power via incremental syndrome calculation.

FIG. 9 is a graph of power versus average number of errors of an embodiment.

FIG. 10 is a flow chart of a method of an embodiment for reducing decoder power via direct error locator polynomial (ELP) root derivation.

### DETAILED DESCRIPTION

The following embodiments generally relate to a data storage device and method for reducing decoder power via incremental syndrome calculation and/or direct error locator polynomial root derivation. In one embodiment, a method for incremental syndrome calculation is provided that is performed in a data storage device comprising a memory. The method comprises: performing a first pipe stage of a decoding process, wherein the first pipe stage comprises calculating a subset of syndrome values of a codeword read from the memory; and performing a second pipe stage of the decoding process, wherein the second pipe stage comprises: using the subset of syndrome values to determine a number of errors in the codeword; and utilizing a full set of syndrome values in the decoding process only in response to the number of errors in the codeword not being less than a threshold.

In another embodiment, a data storage device is provided comprising a memory and one or more processors. The one or more processors, individually or in combination, are configured to: calculate a subset of syndrome values of a codeword; based on the subset of syndrome values, determine if a number of errors in the codeword is less than a threshold; in response to determining that the number of errors is less than the threshold, correct the errors in the codeword; and in response to determining that the number of errors is not less than the threshold: calculate remaining syndrome values of the codeword; calculate an error locator polynomial based on a full set of syndrome values; find roots of the error locator polynomial to determine locations of the errors in the codeword; and correct the errors in the codeword.

In yet another embodiment, a data storage device is provided comprising: a memory; and means for: calculating syndrome values of a codeword read from the memory; calculating an error locator polynomial from the syndrome values; determining a number of errors in the codeword; and in response to the number of errors being at predetermined number of errors, using a look-up table to determine locations of the errors in the codeword; and correcting the errors in the codeword.

Other embodiments are possible, and each of the embodiments can be used alone or together in combination. Accordingly, various embodiments will now be described with reference to the attached drawings.

### Embodiments

The following embodiments relate to a data storage device (DSD). As used herein, a “data storage device” refers to a non-volatile device that stores data. Examples of DSDs include, but are not limited to, hard disk drives (HDDs), solid state drives (SSDs), tape drives, hybrid drives, etc. Details of example DSDs are provided below.

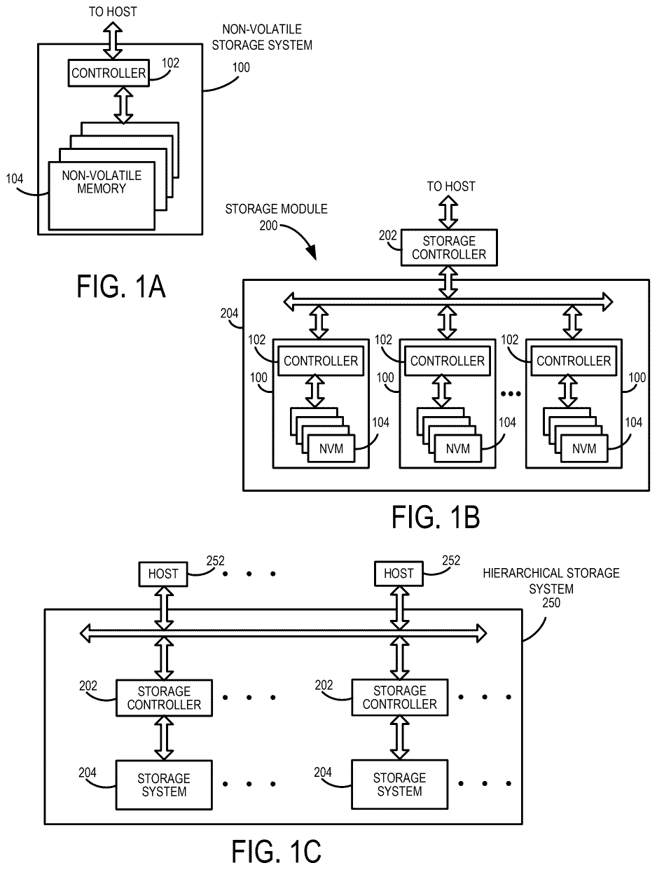

Examples of data storage devices suitable for use in implementing aspects of these embodiments are shown in FIGS. 1A-1C. It should be noted that these are merely examples and that other implementations can be used. FIG. 1A is a block diagram illustrating the data storage device 100 according to an embodiment. Referring to FIG. 1A, the data storage device 100 in this example includes a controller 102 coupled with a non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. The controller 102 interfaces with a host system and transmits command sequences for read, program, and erase operations to non-volatile memory die 104. Also, as used herein, the phrase “in communication with” or “coupled with” could mean directly in communication/coupled with or indirectly in communication/coupled with through one or more components, which may or may not be shown or described herein. The communication/coupling can be wired or wireless.

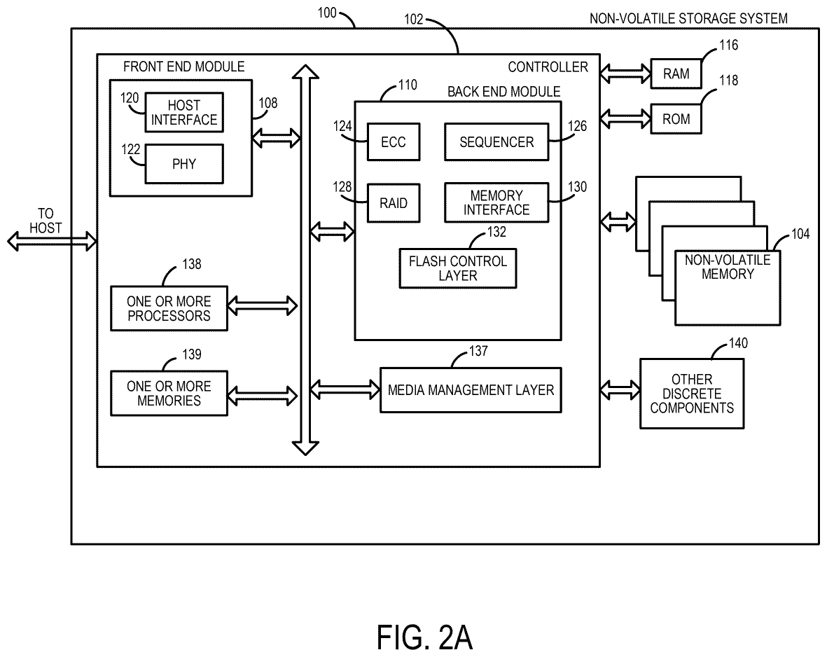

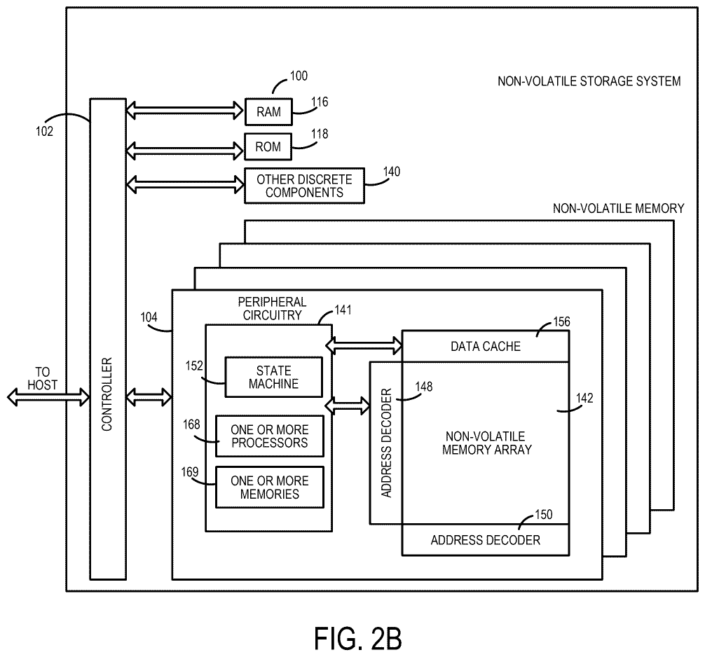

The controller 102 (which may be a non-volatile memory controller (e.g., a flash, resistive random-access memory (ReRAM), phase-change memory (PCM), or magnetoresistive random-access memory (MRAM) controller)) can include one or more components, individually or in combination, configured to perform certain functions, including, but not limited to, the functions described herein and illustrated in the flow charts. For example, as shown in FIG. 2A, the controller 102 can comprise one or more processors 138 that are, individually or in combination, configured to perform functions, such as, but not limited to the functions described herein and illustrated in the flow charts, by executing computer-readable program code stored in one or more non-transitory memories 139 inside the controller 102 and/or outside the controller 102 (e.g., in random access memory (RAM) 116 or read-only memory (ROM) 118). As another example, the one or more components can include circuitry, such as, but not limited to, logic gates, switches, an application specific integrated circuit (ASIC), a programmable logic controller, and an embedded microcontroller.

In one example embodiment, the non-volatile memory controller 102 is a device that manages data stored on non-volatile memory and communicates with a host, such as a computer or electronic device, with any suitable operating system. The non-volatile memory controller 102 can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware (and/or other metadata used for housekeeping and tracking) to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC) (e.g., dual-level cells, triple-level cells (TLC), quad-level cells (QLC), etc.) or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, the data storage device 100 may be a card-based system, such as a secure digital (SD) or a micro secure digital (micro-SD) card. In an alternate embodiment, the data storage device 100 may be part of an embedded data storage device.

Although, in the example illustrated in FIG. 1A, the data storage device 100 (sometimes referred to herein as a storage module) includes a single channel between controller 102 and non-volatile memory die 104, the subject matter described herein is not limited to having a single memory channel. For example, in some architectures (such as the ones shown in FIGS. 1B and 1C), two, four, eight or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile data storage devices 100. As such, storage module 200 may include a storage controller 202 that interfaces with a host and with data storage device 204, which includes a plurality of data storage devices 100. The interface between storage controller 202 and data storage devices 100 may be a bus interface, such as a serial advanced technology attachment (SATA), peripheral component interconnect express (PCIe) interface, double-data-rate (DDR) interface, or serial attached small scale compute interface (SAS/SCSI). Storage module 200, in one embodiment, may be a solid-state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective data storage device 204. Host systems 252 may access memories within the storage system 250 via a bus interface. In one embodiment, the bus interface may be a Non-Volatile Memory Express (NVMe) or Fibre Channel over Ethernet (FCoE) interface. In one embodiment, the system illustrated in FIG. 1C may be a rack mountable mass storage system that is accessible by multiple host computers, such as would be found in a data center or other location where mass storage is needed.

Referring again to FIG. 2A, the controller 102 in this example also includes a front-end module 108 that interfaces with a host, a back-end module 110 that interfaces with the one or more non-volatile memory die 104, and various other components or modules, such as, but not limited to, a buffer manager/bus controller module that manage buffers in RAM 116 and controls the internal bus arbitration of controller 102. A module can include one or more processors or components, as discussed above. The ROM 118 can store system boot code. Although illustrated in FIG. 2A as located separately from the controller 102, in other embodiments one or both of the RAM 116 and ROM 118 may be located within the controller 102. In yet other embodiments, portions of RAM 116 and ROM 118 may be located both within the controller 102 and outside the controller 102.

Front-end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, serially attached small computer system interface (SAS), Fibre Channel, universal serial bus (USB), PCIe, and NVMe. The host interface 120 typically facilitates transfer for data, control signals, and timing signals.

Back-end module 110 includes an error correction code (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. The controller 102 in this example also comprises a media management layer 137 and a flash control layer 132, which controls the overall operation of back-end module 110.

The data storage device 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two-dimensional and/or three-dimensional configuration. Non-volatile memory die 104 further includes a data cache 156 that caches data and address decoders 148, 150. The peripheral circuitry 141 in this example includes a state machine 152 that provides status information to the controller 102. The peripheral circuitry 141 can also comprise one or more components that are, individually or in combination, configured to perform certain functions, including, but not limited to, the functions described herein and illustrated in the flow charts. For example, as shown in FIG. 2B, the memory die 104 can comprise one or more processors 168 that are, individually or in combination, configured to execute computer-readable program code stored in one or more non-transitory memories 169, stored in the memory array 142, or stored outside the memory die 104. As another example, the one or more components can include circuitry, such as, but not limited to, logic gates, switches, an application specific integrated circuit (ASIC), a programmable logic controller, and an embedded microcontroller.

In addition to or instead of the one or more processors 138 (or, more generally, components) in the controller 102 and the one or more processors 168 (or, more generally, components) in the memory die 104, the data storage device 100 can comprise another set of one or more processors (or, more generally, components). In general, wherever they are located and however many there are, one or more processors (or, more generally, components) in the data storage device 100 can be, individually or in combination, configured to perform various functions, including, but not limited to, the functions described herein and illustrated in the flow charts. For example, the one or more processors (or components) can be in the controller 102, memory device 104, and/or other location in the data storage device 100. Also, different functions can be performed using different processors (or components) or combinations of processors (or components). Further, means for performing a function can be implemented with a controller comprising one or more components (e.g., processors or the other components described above).

Returning again to FIG. 2A, the flash control layer 132 (which will be referred to herein as the flash translation layer (FTL) handles flash errors and interfaces with the host. In particular, the FTL, which may be an algorithm in firmware, is responsible for the internals of memory management and translates writes from the host into writes to the memory 104. The FTL may be needed because the memory 104 may have limited endurance, may be written in only multiples of pages, and/or may not be written unless it is erased as a block. The FTL understands these potential limitations of the memory 104, which may not be visible to the host. Accordingly, the FTL attempts to translate the writes from host into writes into the memory 104.

The FTL may include a logical-to-physical address (L2P) map (sometimes referred to herein as a table or data structure) and allotted cache memory. In this way, the FTL translates logical block addresses (“LBAs”) from the host to physical addresses in the memory 104. The FTL can include other features, such as, but not limited to, power-off recovery (so that the data structures of the FTL can be recovered in the event of a sudden power loss) and wear leveling (so that the wear across memory blocks is even to prevent certain blocks from excessive wear, which would result in a greater chance of failure).

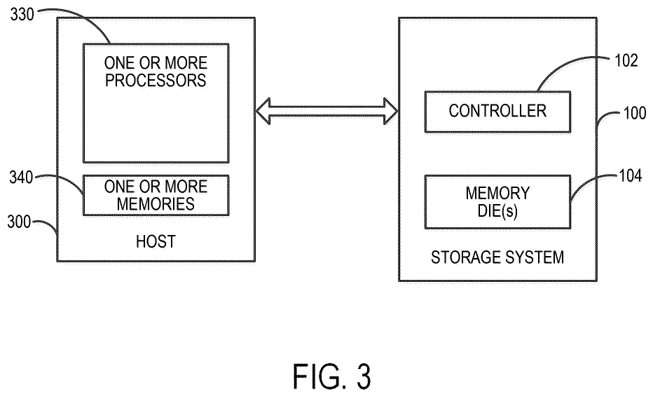

Turning again to the drawings, FIG. 3 is a block diagram of a host 300 and data storage device 100 of an embodiment. The host 300 can take any suitable form, including, but not limited to, a computer, a mobile phone, a tablet, a wearable device, a digital video recorder, a surveillance system, etc. The host 300 in this embodiment (here, a computing device) comprises one or more processors 330 and one or more memories 340. In one embodiment, computer-readable program code stored in the one or more memories 340 configures the one or more processors 330 to perform the acts described herein as being performed by the host 300. So, actions performed by the host 300 are sometimes referred to herein as being performed by an application (computer-readable program code) run on the host 300. For example, the host 300 can be configured to send data (e.g., initially stored in the host's memory 340) to the data storage device 100 for storage in the data storage device's memory 104.

As part of the machine learning (ML)/artificial intelligence (AI) revolution, Large Language Models (LLMs) and Multimodal Models continue to grow rapidly approaching more than a trillion parameters. With the wide-spread usage of such huge models, fast inference capabilities are expected to dominate the AI hardware market. A key component in supporting fast inference of LLMs is the use of DRAM-based High Bandwidth Memories (HBM) for storing and accessing the model parameters/weights. DRAM scaling challenges and slowdown in nodal transitions can lead to an “AI memory wall” problem. Given that LLM inferencing mainly involves read intensive memory workload, a High Bandwidth Flash (HBF) solution can be used to address the above needs with the highest density 3D NAND flash technology. In one embodiment, HBF can be implemented as BICS 3D NAND using a CMOS directly bonded to Array (CBA) design that bonds a 3D NAND memory array on top of an input/output (I/O) die made using logic process technology.

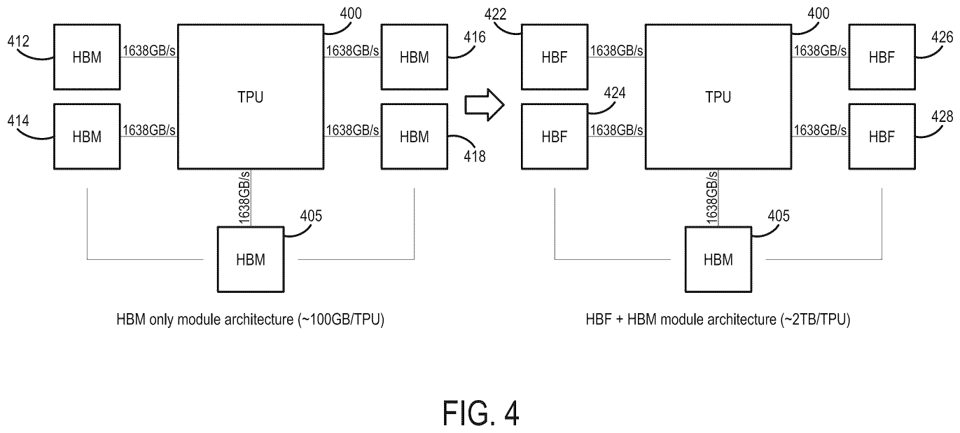

FIG. 4 is a diagram showing that HBF can replace some HBM stacks. As shown in FIG. 4, in an HBM-only architecture, a Tensor Processing Unit (TPU) 400, which is a custom-developed application-specific integrated circuit (e.g., controller/one or more processors) used to accelerate machine learning workloads, is coupled with a plurality of HBMs 405, 412, 414, 416, 418. This example architecture can provide ~100 GB/TPU. In contrast, when HBMs 412, 414, 416, 418 are replaced with HBF 422, 424, 426, 428, the resulting example HBF-plus-HBM architecture can provide ~2 TB/TPU.

As seen from this example, an HBF-based architecture can enable significantly higher memory capacity at substantially lower cost, mitigating the “AI memory wall” challenge. In order to provide a suitable alternative to an HBM-based architecture, an HBF-based architecture may need to satisfy several requirements, such as, for example, support the very high bandwidth of HBMs (e.g., 1.6 TB/see for a HBM4 equivalent solution), have a very low read latency (e.g., in the order of ~1-3 us), exhibit a very low power consumption (e.g., <1pJ/bit), and support a large number of program/erase (P/E) cycles (e.g., 16K-3M). In order to achieve the low latency and high endurance requirement, an HBF-based architecture in one embodiment is a Low Latency SLC-based Flash memory (LLF).

One of the key challenges in implementing an HBF-based architecture is that Flash memories, as opposed to DRAM, exhibit relatively high bit error rates, especially as the memory wears out after large number of program-erase (P/E) cycles. As such, an efficient ECC solution may be required that satisfies several requirements: (1) very high throughput decoding (overall>1.6 TB/sec), (2) very low latency (~100 ns=0.1 us) with small variation to maintain tight Quality of Service (QoS), (3) very low power consumption (<0.5 pJ/bit), and (4) ability to correct up to ~0.3%-0.6% bit error rate with minimal ECC overprovisioning. Due to the requirement for low decoding latency variations (tight QoS) and the relatively low ECC overprovisioning needed for the target bit error rates, one suitable ECC candidate for an HBF-based architecture is an algebraic coding solution, such as a binary Bose-Chaudhuri-Hocquenghem (BCH) codes.

BCH codes are well known in the art since their invention in 1959. There are several decoding schemes for BCH codes. In general, there are three steps in the decoding procedure: (1) calculate the syndrome, (2) calculate the error locator polynomial from the syndrome, and (3) find the error locations and error values (as the zeros of the error locator polynomial). Common BCH decoding algorithms for calculating the error locator polynomial are: Peterson-Gorenstein-Zierler (PGZ), Berlekamp-Massey (BM) (the most commonly used algorithm), Extended Euclidean algorithm, and a direct solver (for very small number of errors). A common algorithm for finding the error locations is the Chien Search algorithm. Finding the error values is commonly done using the Forney algorithm, but this is relevant only for non-binary BCH codes, which may not be suitable for an HBF-based architecture where a binary BCH code is the suitable solution.

To summarize, a common approach for decoding a binary BCH code involves the following three steps: (1) calculate the syndrome, (2) calculate an error location polynomial based on the syndrome using the BM algorithm, and (c) calculate the error locations by finding the roots of the error locator polynomial using a Chien search. However, designing a BCH solution that provides very high throughput and low latency with ultra low power consumption can be highly challenging. The following embodiments provide a method for significantly reducing the energy consumption (>X3) of a high throughput BCH decoder by using incremental syndrome calculation, enabling resolution of the common error cases with very low energy consumption per bit.

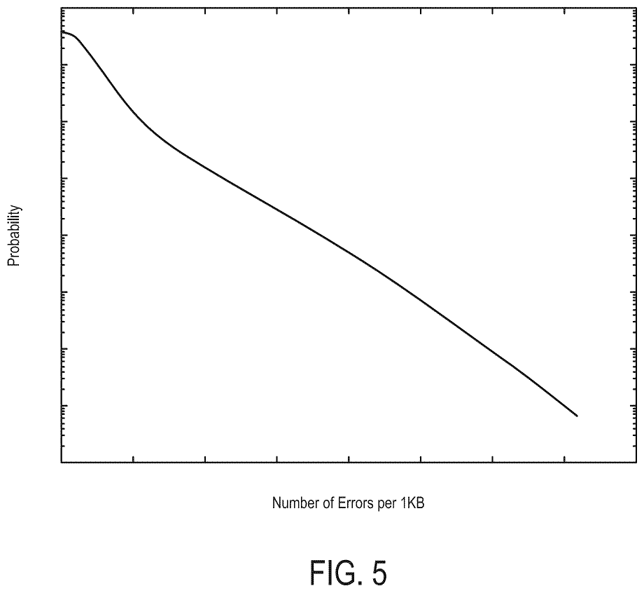

By way of background, the bit error rate (BER) distribution across memory pages and across memory conditions and lifetime (disturbs, temperatures, DR, P/E cycles, etc.) is highly variable. However, in the majority of cases, the BER is very low and only in rare cases is high BER exhibited. FIG. 5 is a graph showing a typical distribution of the number of errors per sector for a Flash (SLC) memory after large number of P/E cycles (e.g., towards memory end of life. In this example, even under such extreme “end of life” conditions, in ~40% of the cases there are no errors, and in ~90% of the cases there are less than three errors per sector. A high number of errors occurs only in very rare cases.

The following embodiments provide a method for significantly reducing the decoder's average energy consumption per bit by optimizing the decoder operation for the common low error cases through incremental calculation of the syndrome.

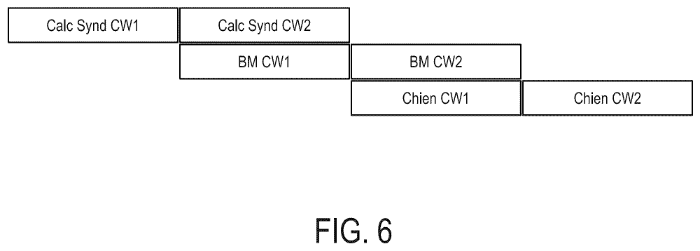

Consider a binary BCH code of length N over the finite field GF(2^{d}) that corrects up to t errors. For example, in protecting 1 KB sectors against up to t=32 bit errors, a length N=1024B data+56B parity=1080B BCH code over the field GF(2¹⁴) can be used. Conventionally, the decoding operation involves the following steps, which are implemented in pipeline and are illustrated in FIG. 6:

Pipe Stage 1: Calculate t syndrome values. This step is usually done on-the-fly as data is fed to the decoder. Each syndrome is of size d bits, hence overall t×d syndrome bits are updated for each input bit. At the end of this step, the t independent syndromes (cyclotomic coset leaders) are expanded to 2×t syndromes.

Pipe Stage 2: Calculate an error locator polynomial based on the 2×t syndromes. This stage is usually done using the Berlekamp-Massey (BM) algorithm. For small values of t, it can also be calculated directly (aka using a “direct solver”). At the end of this stage, the actual number of errors is identified.

Pipe Stage 3: Find the roots of the error location polynomial, which indicate the error locations and correct the errors. This stage is usually done using the Chien Search algorithm by evaluating the error locator polynomial at all possible field elements to identify the roots which zero the polynomial.

Consider the common case for an SLC Flash memory where there are no errors within the codeword. In this case, the syndromes computed in Pipe State 1 are all zeroed. Once this condition is identified, decoding can be terminated, and no further steps need to be performed. Furthermore, consider other common cases where there is a small number of errors in the codeword (e.g., one or two errors). In these cases, a very small number of syndromes may be used to correct the errors. Theoretically, one (independent) syndrome per error may be needed. Hence, for correcting up to two errors, only two syndromes (S1 and S3) may be used. In such simple cases, simplified decoding algorithms may be used instead of the “full blown” BM and Chien algorithms in order to complete the decoding. (An example such a simplified decoders for the case of one or two errors is described below.) As in the vast majority of cases, the number of errors is significantly smaller than t, then calculating t syndromes in decoding Pipe Stage 1 is not required and wasteful in terms of the decoding energy invested per bit (J/bit).

In order to optimize the decoder energy consumption, especially given that this can be a critical requirement for high bandwidth memory applications, the following decoding scheme based on incremental syndrome calculation can be used. In one embodiment, the syndrome calculation is split into two (or potentially more) pipe stages, wherein, in a first pipe stage, a minimal number of syndromes is computed that is sufficient for covering the common error cases. The remaining syndromes are computed in a following pipe stage on demand, only for the rare cases where the identified number of errors exceeds a threshold. This scheme may increase the decoding latency in the rare cases but will dramatically decrease the decoder's average energy consumption. Given that BCH decoding latency can be designed to be very low anyway and that energy consumption metric is critical, this tradeoff can be highly favorable.

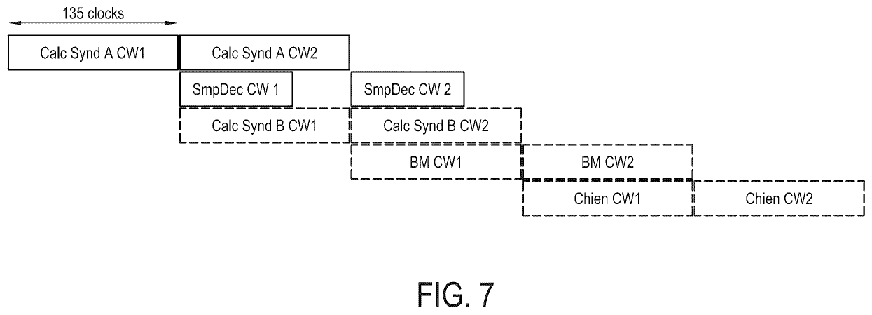

As an example, consider a t=32 error correcting length N=1080B BCH code. Further assume that the decoder operates at a high rate of 8B per clock and hence decodes every codeword within 1080/8=135 clocks. In Pipe Stage 1, we may compute only four syndrome values (S1, S3, S5, S7) and only in rare cases where the number of errors is greater than two do we compute the remaining 28 syndrome values. In this case, the decoder pipeline may be implemented as follows, and as shown in FIG. 7.

Pipe Stage 1: Calculate t_{A}=4 syndrome values (S1, S3, S5, S7). This step is usually done on-the-fly as data is fed to the decoder. Each syndrome is of size d bits, hence overall t_{A}×d=4×d syndrome bits are updated for each input bit.

Pipe Stage 2: This stage will include two parallel operations:
(1) Simple Decoder for the low error cases. For example, the simple decoder may solves 0/1 errors:
If S1=S3=S5=S7=0, then no errors were detected, decoding is done
If S3=(S1)³; S5=(S1)⁵; S7=(S1)⁷→single error was detected, correct error at location j=log _{α}(S1), where α is the primitive element of the field GF(2¹⁴)
(2) Calculate remaining t_{B}=28 syndrome values. In this stage, t_{B}×d=28×d syndrome bits are updated for each input bit

Clearly, in the common cases where the number of errors is sufficiently small to be identified and corrected by the simple decoder, within few clock cycles of pipe stage 2 (e.g., one or two clock cycles) the overall decoding operation is terminated, halting the calculation of the remaining syndromes and remaining Pipe Stages 3 and 4. In these cases, the decoder's overall energy consumption per bit is dramatically reduced, as the decoder only computed four syndromes in Pipe Stage 1 and performed~1-2 clock cycles (out of 135 clock cycles) of Pipe Stage 2 before successfully terminating the decoding.

Pipe Stage 3: Calculate an error locator polynomial based on the 2×t syndromes. This stage is usually done using the Berlekamp-Massey (BM) algorithm.

Pipe Stage 4: Find the roots of the error location polynomial which indicate the error locations and correct the errors. This stage is usually done using the Chien Search algorithm by evaluating the error locator polynomial at all possible field elements to identify the roots which zero the polynomial.

The average energy consumption of the proposed decoder compared to a conventional decoder is significantly reduced. In the example above, for the common cases of 0 or 1 errors per codeword, the decoder energy consumption is ~4/32=~12.5% compared to a conventional decoder, since only four syndromes out of 32 syndromes were calculated for sake of decoding.

One consideration in determining the number of syndromes that need to be calculated during the first pipe stage (t_{A}) may be the undetected error rate that needs to be satisfied. Relying on a small number of syndromes to determine that a small number of errors (e.g., 0, 1, or 2 errors) has occurred introduces a risk of an undetected error. An event with a large number of errors might “disguise” as an event with a small number of errors when observing only a small number of syndromes. In this case, the simple decoder (used in Pipe Stage 2 of the above example) may mistakenly determine that there is a small number of errors, wrongly correct them, and terminate the decoding, thereby sending out wrong information, which can lead to a catastrophic undetected error event. In order to avoid this, a sufficiently large number of syndromes can be calculated during the first pipe stage.

The undetected error probability of the proposed decoding scheme that calculates t_{A} syndromes in the first stage and tries to correct up to r errors using the simple decoder in the second stage, can be approximated by the following equation:

$$Pr ( Undetected error \vert {t}_{A} , r ) = {\sum }_{j = 2 \cdot {t}_{A} + 1}^{N} ( \begin{matrix}N \\ r\end{matrix} ) \cdot {2}^{- {t}_{A} \cdot d} \cdot ( \begin{matrix}N \\ j\end{matrix} ) \cdot {p}^{j} \cdot {( 1 - p )}^{N - j}$$

where N is the code length, d is the finite field characteristic, and p is the Flash memory error probability.

In case that the undetected error rate is not sufficiently low for the application, a larger number of syndromes t_{A} can be computed in the first decoding stage, or the simple decoder can handle a smaller number of error cases r.

As an example, for t_{A}=4, r=1, p≈0.03%, d=14 and N=1080B, the undetected error probability would be Pr(Undetected error|t_{A}, r)≈10⁻¹⁶

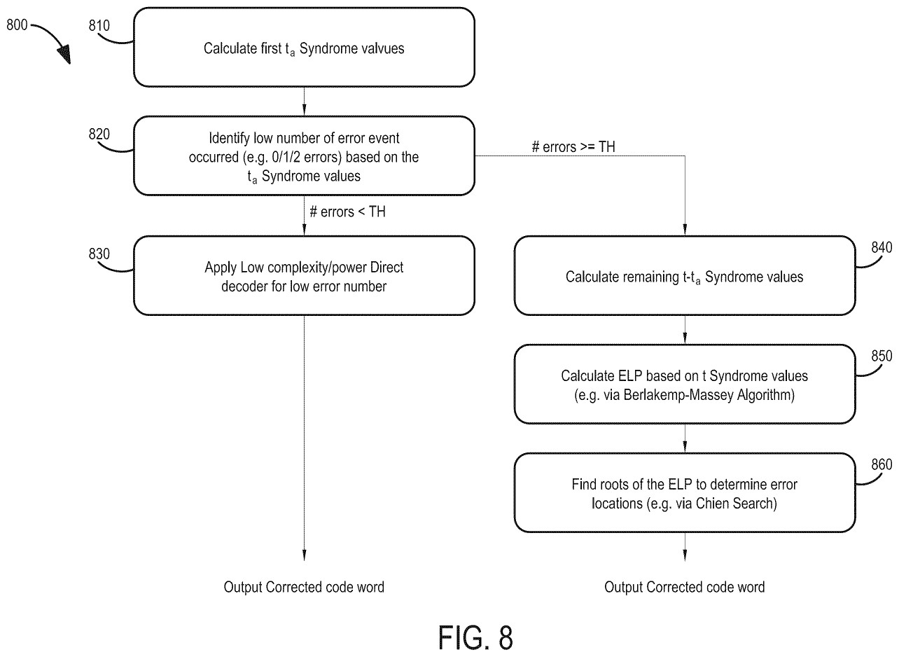

FIG. 8 is a flow chart 800 of a method of an embodiment for reducing decoder power via incremental syndrome calculation. As shown in FIG. 8, in this embodiment, after the controller 102 of the data storage device 100 reads a codeword of data from the memory 104 (e.g., in response to a read command from the host 300), the controller 102 calculates a subset of syndrome values (810) and identifies if the number of error events that occurred based on the syndrome values is less than a threshold (820). This can be done, for example, via a direct error locator polynomial (ELP) calculation for a small enough subset of syndrome values or using a scaled-down Berlekamp-Massey (BM) operation on the subset of syndrome values. If the number of errors is less than the threshold, the controller 102 applies a low-complexity/low-power direct decoder, such as the one described below (830), which result in a corrected code work being outputted to the host 300 (e.g., in response to a read command). If the number of errors is not less than the threshold, the controller 102 calculates the remaining number of syndrome values in the set (840), calculates the ELP based on the entire set of syndrome values (850), and then finds the root of the ELP to determine error locations (860), which result in a corrected code work being outputted (e.g., returned to the host 300 in response to a read command).

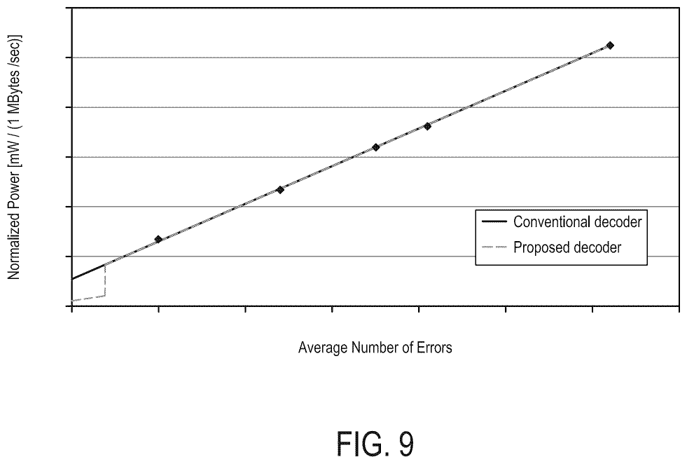

There are several advantages associated with these embodiments. For example, these embodiments can be used to significantly reduce the average energy consumption (J/bit) of the BCH decoder. This can be a critical metric for high bandwidth applications, such as High Bandwidth Memories (HBM), which may target very high throughputs (e.g., 1.6 TB/sec for HBM4). Also, as shown in the graph in FIG. 9, the low number of errors is the common case in a Flash memory and having a high number of errors is an extremely rare event; thus, the overall saving in the average decoder's J/bit of these embodiments is significant. It is estimated that, for realistic use cases, the saving can be 60%-90% depending on the exact memory BER distribution, which changes along the memory lifetime and according to the operational conditions. As also shown in FIG. 9, a decoder of these embodiments may exhibit a jump in energy consumption when the number of errors surpass a threshold (e.g., more than 0/1/2 errors), while a conventional decoder may exhibit a monotonic linear increase in the energy consumption with the number of errors.

In another embodiment, a method is provided for reducing the energy consumption of a BCH decoder through an ultra low power direct solver for the most common error events. As mentioned above, a common algorithm for finding the error locations is the Chien Search algorithm. The Chien decoding stage is the most power consuming stage, as it requires N evaluations of the error locator polynomial (ELP), where N is the BCH code length. In this embodiment, a full direct solver is provided that replaces the high energy consuming Chien Search with an ultra low power direct solver for the most common error cases. That is, this embodiment can significantly reduce the decoder's average energy consumption per bit through an ultra low power direct solver that replaces the high energy consuming Chien Search for the most common error cases.

As mentioned above, Pipe Stage 3 of a conventional decoding operation finds the roots of the ELP, which indicate the error locations and correct the errors. This stage is usually done using the Chien Search algorithm by evaluating the ELP at all possible field elements to identify the roots which zero the polynomial. This stage requires performing N evaluations of the ELP, where each evaluation requires up to t multiplications and t−1 additions over the field. For the code provided in the above example, the Chien stage would require up to N*t=276,480 multiplications and N*t=276,480 additions over the GF(2¹⁴) field, which consumes a significant amount of energy (→the main part of the decoder energy consumption).

In order to optimize the decoder energy consumption, especially given that this can be a critical requirement for high bandwidth memory applications, this embodiment replaces the high energy consuming Chien Search with a direct solver of the ELP for the most common error cases (e.g., in >90% of the cases less than three errors occur in the codeword).

Specifically, this embodiment focuses on the following three common cases:
0 Errors—Trivial case: All syndromes calculated in Stage 1 are zeroed→Chien search is skipped, and decoding is terminated successfully.
1 Error—a degree 1 ELP is calculated during the BM stage: AΛ(x)=1+Λ₁·x, where Λ₁=S₁ and Λⱼ=0 for j=2, . . . , t.

In this simple case, the ELP can be calculated directly without running the full BM algorithm. For this case, the energy consuming Chien Search stage is replaced by a direct solution for the ELP roots as follows:

1+S₁·x=0→x=S₁⁻¹=α⁻¹,

where α is the primitive element of the field GF(2^{d}) and j is the error location.

Hence, j=log α S₁, which can be calculated using an offline calculated Look Up Table (LUT) of size 2^{d}×d, that stores the logarithm j for each field element β=α^{j}∈GF(2^{d})→j=LUT_{log α}(S₁)

Note that in the direct calculation described above, N field multiplications and N field additions that would be required by a Chien Search are replaced with a single LUT access, resulting ~1/N of the energy consumption.

2 Errors—a degree 2 ELP is calculated during the BM stage:

$$Λ ( x ) = 1 + {Λ}_{1} \cdot x + {Λ}_{2} \cdot {x}^{2} , where {Λ}_{1} = {S}_{1} , {Λ}_{2} = \frac{{S}_{3} + {S}_{1}^{3}}{{S}_{1}} and {Λ}_{j} = 0 for j = 3 , … , t .$$

In this simple case, the ELP can also be calculated directly without running the full BM algorithm. For this case, the energy consuming Chien Search stage is replaced by a direct solution for the ELP roots as follows:

$$1 + {Λ}_{1} \cdot x + {Λ}_{2} \cdot {x}^{2} = 0 ( divide by {Λ}_{2} )$$

$$\frac{1}{{Λ}_{2}} + \frac{{Λ}_{1}}{{Λ}_{2}} \cdot x + {x}^{2} = 0 ( substitude by x = \frac{{Λ}_{1}}{{Λ}_{2}} \cdot y )$$

$$\frac{1}{{Λ}_{2}} + \frac{{Λ}_{1}^{2}}{{Λ}_{2}^{2}} \cdot y + \frac{{Λ}_{1}^{2}}{{Λ}_{2}^{2}} \cdot {y}^{2} = 0 ( divide by \frac{{Λ}_{1}^{2}}{{Λ}_{2}^{2}} )$$

$$\frac{{Λ}_{2}}{{Λ}_{1}^{2}} + y + {y}^{2} = 0$$

$$y = {LUT}_{Q} ( \frac{{Λ}_{2}}{{Λ}_{1}^{2}} ) ,$$

where LUT_{Q}(β) is a 2^{d}×d offline calculated LUT which stores for each field element β∈GF(2^{d}), the solution y of the Quadratic equation

β+y+y²=0

Finally, the roots of the ELP x₁ and x₂ can be computed as

$${x}_{1} = \frac{{Λ}_{1}}{{Λ}_{2}} \cdot y and {x}_{2} = \frac{1}{{Λ}_{2} \cdot {x}_{1}}$$

Note that as we are actually interested in the power of the roots, which provide the error locations, then all calculations may be performed in the power domain (i.e., based on the power representations of the field elements).

### More Specifically:

Let LUT_{Q} be defined in the power domain—i.e. k=LUT_{Q}(l), where α¹+α^{2k}+α^{k}=0

$$Let {Λ}_{1} = {a}^{{l}_{1}} , {Λ}_{2} = {a}^{{l}_{2}} \to \frac{{Λ}_{1}}{{Λ}_{2}} = {a}^{{l}_{1} - {l}_{2}} , \frac{{Λ}_{2}}{{Λ}_{1}^{2}} = {a}^{{l}_{2} - 2 \cdot {l}_{1}}$$

$$Then :$$

$${l}_{1} = {LUT}_{log a} ( {Λ}_{1} ) = {LUT}_{log a} ( {S}_{1} )$$

$${l}_{2} = {LUT}_{log a} ( {Λ}_{2} ) = {LUT}_{log a} ( \frac{{S}_{3} - {S}_{1}^{3}}{{S}_{1}} )$$

$$Let y = {a}^{k} , {x}_{1} = {x}^{- {j}_{1}} , {x}_{2} = {a}^{- {j}_{2}}$$

$$Then :$$

$$k = {LUT}_{Q} ( l ) , where l = mod ( {l}_{2} - 2 \cdot {l}_{1} , {2}^{d} - 1 )$$

$$\begin{matrix}{j}_{1} = mod ( {l}_{2} - {l}_{1} - k , {2}^{d} - 1 ) & ( {x}_{1} =\end{matrix} \frac{{Λ}_{1}}{{Λ}_{2}} \cdot y \to {a}^{- {j}_{1}} = {a}^{{l}_{1} - {l}_{2}} \cdot {a}^{k} )$$

$$\begin{matrix}{j}_{2} = mod ( {l}_{2} - {l}_{1} , {2}^{d} - 1 ) & ( {x}_{1} \cdot {x}_{2} = \frac{1}{{Λ}_{2}}\end{matrix} \to {a}^{- {j}_{1}} \cdot {a}^{- {j}_{2}} = {a}^{- {l}_{2}} )$$

The proposed scheme based on a low complexity direct solution of a quadratic ELP equation for the case of two errors, replaces a high energy consuming Chien Search that requires N evaluations of a degree 2 ELP (N*2 field multiplications and N*2 field additions) with a simple calculation involving 3 LUT accesses and 4 regular additions over d bit numbers, consuming negligible energy.

In an additional embodiment, we propose an efficient method for the implementation of the LUT_{log α} table mentioned in the simple 1-error and 2-error correcting scheme above. The naïve implementation of the table requires a memory of size 2^{d}×d, that stores the logarithm j for each field element β=α^{j}∈GF(2^{d}) entries. For large field size d, maintaining a 2^{d}×d LUT may be costly and require a large memory. In order to reduce the cost, we propose a low complexity implementation for cases of non-prime d which can be decomposed as d=k·l for some integers k and l. In this case, the field GF(2^{d}) contains a subfield GF(2^{k}) and an implementation based on reduced size LUT can be used. For example, assuming d=14=7·2, then the field GF(2¹⁴) contains a subfield GF(2⁷). Without loss of generality, we will describe the method for d=14:

Given a field element a=α^{j}), we want to find j.

We break j down as,

J=j₀*127+j₁,j₀∈{0,1, . . . ,128},/₁,∈{0,1, . . . ,126}

The following steps are executed.

Step 1: Calculate {square root over (a⁽²^{^{d}}^{-1)/(2}^{^{k}}^{-1)=a}¹²⁹)}. This calculation results in an element which is part of the subfield GF(2^{k})=GF(2⁷). It is also an efficient operation because the exponentiation a¹²⁸ is a linear operation for a field with characteristic 2 (i.e. it can be computed through a multiplication of a fixed d×d matrix M₁₂₈ with the d bits vector representing element a). We thus have a¹²⁹a¹²⁸·α, which can be computed via a linear operation and a single generic field multiplication ((M₁₂₈·a)·a).

The result satisfies:

a¹²⁹=α^{129j}=α^{129·127j}^{ₒ}^{+129·j}^{₁}^{=α}^{129·j}^{₁}

Step 2: The 7 least significant bits of the term α^{129·j}^{₁}, are unique. We use these 7 bits as an input to a lookup table with 127 entries, each entry containing 21 bits, as follows:
j₁-7 bits
α^{-j}^{₁}−14 bits

### Step 3:

Multiply the input α^{j} by α^{-j}^{₁} obtained in the last step. The result is α^{127·j}^{ₒ}

### Step 4:

The value α^{127·j}^{₀} has only 129 different possibilities (128 excluding the trivial value of 1).

Compare the resulting α^{127·j}^{₀}, 14 bits, against its precomputed 129 values, to obtain j₀.

### Step 5:

Output, j=j₀*127+j₁

(j₀ was calculated in step 4, j₁ in step 2)

The algorithm described above requires, instead of a lookup table of size 2¹⁴×14, a much smaller lookup table of size 127×21 as well as a comparison table of size 129×14 and a few multiplication and addition operations. The benefit of using this approach increases with larger field size d.

In yet another embodiment, we propose an efficient method for the direct solver in the case of t=2, that avoids usage of the potentially large 2^{d}×d table LUT_{Q} as described above. We start from the error locator polynomial of degree 2:

Λ(x)=ax²+bx+c,

First, we equate the ELP to zero and apply the substitution

$$x = \frac{by}{a} :$$

$${ax}^{2} + bx + c = 0 , x = \frac{by}{a} \qquad ( 1 )$$

$$\frac{{b}^{2}}{{a}^{2}} {y}^{2} + \frac{{b}^{2}}{{a}^{2}} y + \frac{c}{a} = 0$$

$${y}^{2} + y + \frac{ac}{{b}^{2}} = 0$$

$${y}^{2} + y = \frac{ac}{{b}^{2}}$$

$$Ay = \frac{ac}{{b}^{2}}$$

The last step is justified where A=Pow2+1, is the sum of the identity matrix of order d and a matrix Pow2 representing the squaring operation, which is linear for a field of characteristic 2.

We also denote

$$Δ {=}^{Δ} \frac{ac}{{b}^{2}} .$$

Now, A is a fixed matrix with rank d−1 whose rightmost column is all zeros. If we remove the rightmost column and the top row, resulting in the matrix Ã which is a square invertible matrix of rank d−1. Correspondingly removing the top row of

$$\frac{ac}{{b}^{2}}$$

(call it \tilde{Δ}) and the bottom row of y to yield \tilde{y} we may write

Ã\tilde{y}=\tilde{Δ} (2)
which is an invertible system of equations. Interestingly, the two original roots y₁, y₂ which solve eq. (1) satisfy y₁+y₂=1, as this is the coefficient of y. This implies that the two roots only differ in their last coordinate, representing the unit in GF(2). Solving eq. (2) by multiplying both sides by (Ã)⁻¹, we get

$$\begin{matrix}\tilde{y} = {( \tilde{A} )}^{- 1} \tilde{Δ} \\ {y}_{1} = [ \begin{matrix}\tilde{y} \\ 0\end{matrix} ] \\ {y}_{2} = [ \begin{matrix}\tilde{y} \\ 1\end{matrix} ]\end{matrix} \qquad ( 3 )$$

yielding the final solution we seek,

$${x}_{1} = \frac{{by}_{1}}{a} , {x}_{2} = \frac{{by}_{2}}{a}$$

Computational complexity of the above proposed approach:
Upon receiving the original coefficients a, b, c, we implement the LUT_{log α} function and express them in their exponential coordinates. To calculate \tilde{Δ}, we exponentiate the log of the fraction

$$Δ = \frac{ac}{{b}^{2}}$$

where the log is implemented as an addition and subtraction (log a+log c−2*log b). From this point, we can calculate \tilde{y} using eq. (3), as the matrix (Ã)⁻¹ is known and pre-calculated offline. Then, implementing the LUT_{log α} function on y₁ and calculating y₂ based on the log of y₁ and the fact that

$${y}_{1} {y}_{2} = \frac{ac}{{b}^{2}} ( log {y}_{1} = log ( a ) + log ( c ) - 2 log ( b ) - log ( {y}_{2} )$$

we may get the log-domain values of x₁, x₂ which also represent their error locations. This concludes the calculation and the corresponding bits may be flipped.

To summarize, replacing the high energy consuming Chien Search by a direct solution for finding the roots of the ELP linear (1 error case) or Quadratic (2 errors case) equation, significantly reduces the BCH decoder energy consumption. This works especially well for Flash technology where the low error case (including the 0 errors case) provide the majority of the error events, while the events with large number of errors that would still use the conventional Chien Search approach are relatively rare. For the direct ELP roots finding, an elegant low complexity and low energy consuming algorithm is provided based on using pre-computed look-up tables.

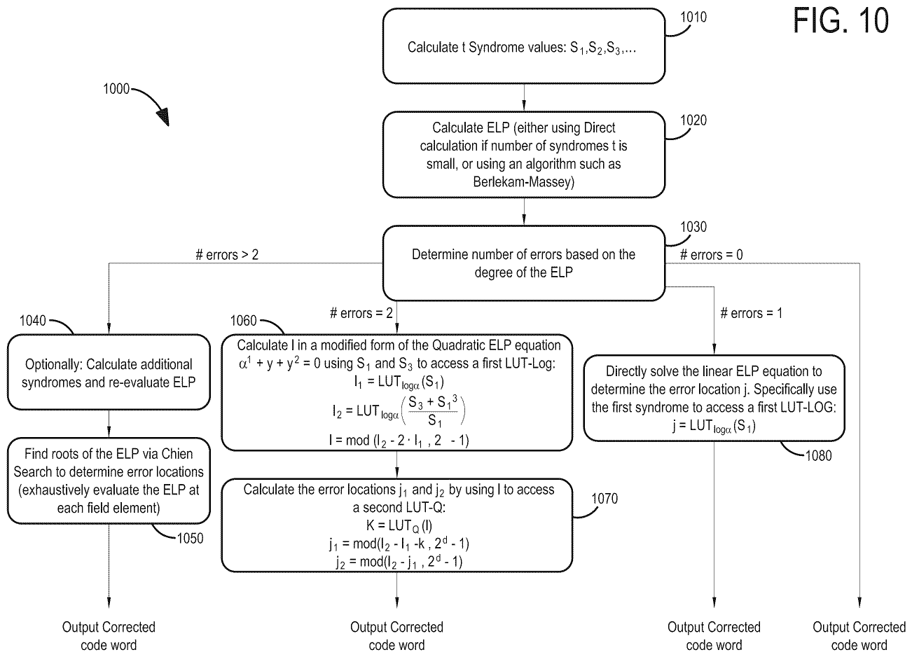

Turning again to the drawings, FIG. 10 is a flow chart 1000 of a method of an embodiment for reducing decoder power via direct error locator polynomial (ELP) root derivation. As shown in FIG. 10, the controller 102 of the data storage device 100 calculates syndrome values of a codeword (1010) and calculates an error locator polynomial (ELP) (1020). The controller 102 then determines a number of errors in the codeword (1030). If the number of errors is greater than two, the controller 102 optionally calculates additional syndrome values and re-evaluates the ELP (1040) and finds the roots of the ELP to file the error locations (1050). If the number of errors is equal to two, the controller 102 calculates a value to access a first look-up table (LUT) (1060) and then calculates error locations using a second LUT (1070). Finally, if the number of errors equals one, the controller 102 directly solves the ELP equation using the first LUT (1080). The corrected codeword can be returned to a host (e.g., in response to a read command from the host.

There are several advantages associated with these embodiments. For example, for the proposed direct ELP roots solver for the one and two error cases, it is estimated that the energy consumption would be in the order of ~N times less compared to the conventional Chien Search used in prior art.

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three-dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements in each column. The columns may be arranged in a two-dimensional configuration, e.g., in an x-z plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three-dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

1. In a data storage device comprising a memory, a method for incremental syndrome calculation comprising:
performing a first pipe stage of a decoding process, wherein the first pipe stage comprises calculating a subset of syndrome values of a first codeword read from the memory;
performing a second pipe stage of the decoding process, wherein the second pipe stage comprises performing the following in parallel:
using the subset of syndrome values of the first codeword to attempt to decode the first codeword; and
calculating remaining syndrome values of the first codeword to obtain a full set of syndrome values of the first codeword, wherein the calculating of the remaining syndrome values of the first codeword is halted in response to the attempt to decode the first codeword being successful; and
in response to the attempt to decode the first codeword not being successful:
performing a third pipe stage of the decoding process, wherein the third pipe stage comprises calculating an error locator polynomial based on the full set of syndrome values of the first codeword; and
performing a fourth pipe stage of the decoding process, wherein the fourth pipe stage comprises:
finding roots of the error locator polynomial to identify locations of errors in the first codeword; and
correcting the errors.

2. The method of claim 1, wherein calculating the subset of syndrome values is done on-the-fly as data from the first codeword is provided to a decoder.

3-4. (canceled)

5. The method of claim 1, wherein the error locator polynomial is calculated using a Berlekamp-Massey (BM) operation.

6. (canceled)

7. The method of claim 1, wherein finding the roots of the error locator polynomial is done using a Chien search.

8. The method of claim 1, wherein finding the roots of the error locator polynomial is done using a look-up table.

9. The method of claim 1, wherein a number of syndrome values in the subset of syndrome values is sufficiently large to account for an undetected error rate.

10. The method of claim 1, further comprising reading the first codeword from the memory in response to a read command from a host and returning a corrected codeword to the host after the decoding process.

11. A data storage device comprising:
a memory; and
one or more processors, individually or in combination, configured to:
perform a first pipe stage of a decoding process, wherein the first pipe stage comprises calculating a subset of syndrome values of a first codeword read from the memory;
perform a second pipe stage of the decoding process, wherein the second pipe stage comprises performing the following in parallel:
using the subset of syndrome values of the first codeword to attempt to decode the first codeword; and
calculating remaining syndrome values of the first codeword to obtain a full set of syndrome values of the first codeword, wherein the calculating of the remaining syndrome values of the first codeword is halted in response to the attempt to decode the first codeword being successful; and
in response to the attempt to decode the first codeword not being successful;
perform a third pipe stage of the decoding process, wherein the third pipe stage comprises calculating an error locator polynomial based on the full set of syndrome values of the first codeword; and
perform a fourth pipe stage of the decoding process, wherein the fourth pipe stage comprises:
finding roots of the error locator polynomial to determine locations of the errors in the first codeword; and
correcting the errors in the first codeword.

12. The data storage device of claim 11, wherein calculating the error locator polynomial is done using a Berlekamp-Massey (BM) operation.

13. The data storage device of claim 11, wherein finding the roots of the error locator polynomial is done using a Chien search.

14. The data storage device of claim 11, wherein finding the roots of the error locator polynomial is done using a look-up table.

15. The data storage device of claim 11, wherein the one or more processors, individually or in combination, are further configured to determine if a number of errors is less a threshold using a direct error locator polynomial calculation.

16. The data storage device of claim 11, wherein the one or more processors, individually or in combination, are further configured to determine if a number of errors is less than a threshold using a scaled-down Berlekamp-Massey (BM) operation.

17. The data storage device of claim 11, wherein a number of syndrome values in the subset of syndrome values is sufficiently large to account for an undetected error rate.

18. The data storage device of claim 11, wherein the first codeword is read from the memory in response to a read command from a host and a corrected codeword is returned to the host after the errors in the first codeword are corrected.

19. The data storage device of claim 11, wherein the memory comprises a three-dimensional memory.

20. (canceled)

21. A data storage device comprising:
a memory; and
means for:
performing a first pipe stage of a decoding process, wherein the first pipe stage comprises calculating a subset of syndrome values of a codeword read from the memory; and
performing a second pipe stage of the decoding process, wherein the second pipe stage comprises performing the following in parallel:
using the subset of syndrome values of the codeword to attempt to decode the codeword; and
calculating remaining syndrome values of the codeword to obtain a full set of syndrome values of the codeword, wherein the calculating of the remaining syndrome values of the codeword is halted in response to the attempt to decode the codeword being successful; and
in response to the attempt to decode the codeword not being successful:
performing a third pipe stage of the decoding process, wherein the third pipe stage comprises calculating an error locator polynomial based on the full set of syndrome values of the codeword; and
performing a fourth pipe stage of the decoding process, wherein the fourth pipe stage comprises:
finding roots of the error locator polynomial to identify locations of errors in the codeword; and
correcting the errors.

22. The method of claim 1, wherein:
performing the second pipe stage of the decoding process further comprises calculating a subset of syndrome values of a second codeword read from the memory;
performing the third pipe stage of the decoding process further comprises:
using the subset of syndrome values of the second codeword to attempt to decode the second codeword; and
calculating remaining syndrome values of the second codeword to obtain a full set of syndrome values of the second codeword, wherein the calculating of the remaining syndrome values of the second codeword is halted in response to the attempt to decode the second codeword being successful; and
performing the fourth pipe stage of the decoding process further comprises calculating an error locator polynomial based on the full set of syndrome values of the second codeword in response to the attempt to decode the second codeword not being successful.

23. The data storage device of claim 11,
performing the second pipe stage of the decoding process further comprises calculating a subset of syndrome values of a second codeword read from the memory;
performing the third pipe stage of the decoding process further comprises:
using the subset of syndrome values of the second codeword to attempt to decode the second codeword; and
calculating remaining syndrome values of the second codeword to obtain a full set of syndrome values of the second codeword, wherein the calculating of the remaining syndrome values of the second codeword is halted in response to the attempt to decode the second codeword being successful; and
performing the fourth pipe stage of the decoding process further comprises calculating an error locator polynomial based on the full set of syndrome values of the second codeword in response to the attempt to decode the second codeword not being successful.
